(19) United States
(12) Patent Application Publication
(10) Pub. No.: US 2022/0123523 A1
(43) Pub. Date: Apr. 21, 2022

(54) SEMICONDUCTOR LASER DEVICE

(71) Applicant: Mitsubishi Electric Corporation, Tokyo (JP)

(72) Inventors: Masato KAWASAKI, Tokyo (JP); Tomotaka KATSURA, Tokyo (JP); Shuichi FUJIKAWA, Tokyo (JP)

(73) Assignee: Mitsubishi Electric Corporation, Tokyo (JP)

(21) Appl. No.: 17/429,366

(22) PCT Filed: Mar. 29, 2019
(86) PCT No.: PCT/JP2019/014338

§ 371 Date: Aug. 9, 2021

(51) Int. Cl. H01S 5/14; H01S 5/40

(52) U.S. Cl. CPC H01S 5/143; H01S 5/4087

(57) ABSTRACT

A semiconductor laser device includes semiconductor laser elements emitting laser beams having different wavelengths from each other and a partial reflection element. The semiconductor laser elements and the partial reflection element constitute respective ends of an external resonator. Further, there is a transmissive wavelength dispersion element located on optical paths of the laser beams between the semiconductor laser elements and the partial reflection element and at a position where the laser beams are superimposed. The transmissive wavelength dispersion element has a wavelength dispersion property, and changes traveling directions of the laser beams in a first plane including the optical axes of the laser beams to combine the laser beams to have one optical axis. Also, there is an asymmetric refraction optical element located on an optical path between the transmissive wavelength dispersion element and the partial reflection element.

### FIELD

The present invention relates to a semiconductor laser device that combines laser beams emitted from a plurality of semiconductor laser elements by using a wavelength dispersion optical element.

### BACKGROUND

In a semiconductor laser element, the laser beam power that can be generated from one light emitting point is low, and the laser beams from a plurality of semiconductor laser elements need to be combined in applications such as laser machining. As a technology for combining laser beams from a plurality of semiconductor laser elements, a semiconductor laser device has been proposed that combines beams from a plurality of semiconductor laser elements onto one optical axis by using an external resonator including a plurality of semiconductor laser elements and a wavelength dispersion optical element. In such a semiconductor laser device, a problem to be addressed is to improve beam focusing performance.

Patent Literature 1 discloses a semiconductor laser device including an external resonator that combines beams from a plurality of semiconductor laser elements by using a dispersive optical element, in which a lens disposed between the dispersive optical element and a partially-reflective mirror reduces cross-coupling oscillation to improve the focusing performance of output beams.

### CITATION LIST

### Patent Literature

Patent Literature 1: US patent Application Laid-open No. 2013/0208361

### SUMMARY

### Technical Problem

With the technology of the related art, the deterioration in the focusing performance due to cross-coupling oscillation can be mitigated, however, there is a problem in that no effect is produced on the deterioration in the focusing performance due to factors other than cross-coupling oscillation.

The present invention has been made in view of the above, and an object thereof is to provide a semiconductor laser device in which laser beams emitted by a plurality of semiconductor laser elements are combined by using a wavelength dispersion optical element and which generates a high-power laser beam with high focusing performance.

### Solution to Problem

In order to solve the above problem and achieve the object, a semiconductor laser device according to the present invention includes: a plurality of semiconductor laser elements to emit laser beams having different wavelengths from each other; a partial reflection element, the semiconductor laser elements and the partial reflection element constituting respective ends of an external resonator; a transmissive wavelength dispersion element located on optical paths of the laser beams between the semiconductor laser elements and the partial reflection element and at a position at which the laser beams are superimposed, the transmissive wavelength dispersion element having a wavelength dispersion property and changing traveling directions of the laser beams in a first plane including optical axes of the laser beams to combine the laser beams to have one optical axis; and an asymmetric refraction optical element located on an optical path between the transmissive wavelength dispersion element and the partial reflection element, an intra-element passage distance in the asymmetric refraction optical element decreasing with a change in a position in a first direction, the intra-element passage distance being a distance by which a laser beam passes through the asymmetric refraction optical element, the first direction being a direction included in the first plane and perpendicular to the optical axis of the laser beams.

### Advantageous Effects of Invention

According to the present invention, a semiconductor laser device, in which laser beams emitted by a plurality of semiconductor laser elements are combined by using a wavelength dispersion optical element, produces an effect of being capable of generating a high-power laser beam with high focusing performance.

### BRIEF DESCRIPTION OF DRAWINGS

FIG. 1 is a schematic diagram illustrating a configuration of a semiconductor laser device according to a first embodiment of the present invention.

FIG. 2 is a schematic diagram illustrating an example of a light focusing state of an aberration-free optical system.

FIG. 3 is a schematic diagram illustrating an example of a light focusing state of an optical system with an aberration.

FIG. 4 is a schematic view illustrating an example of a configuration of an asymmetric refraction optical element illustrated in FIG. 1.

FIG. 5 is a schematic view illustrating a configuration of an asymmetric refraction optical element, which is a modification of FIG. 4.

FIG. 6 is a schematic diagram illustrating a configuration of a semiconductor laser device according to a second embodiment of the present invention.

FIG. 7 is a schematic diagram illustrating a configuration of a semiconductor laser device according to a third embodiment of the present invention.

FIG. 8 is a schematic diagram illustrating a configuration of a semiconductor laser device according to a fourth embodiment of the present invention.

FIG. 9 is a schematic view illustrating a configuration of a semiconductor laser array element illustrated in FIG. 8.

FIG. 10 is a schematic diagram illustrating a configuration of a semiconductor laser device according to a fifth embodiment of the present invention.

FIG. 11 is a perspective view illustrating an example of a configuration of a rotating optical element illustrated in FIG. 10.

FIG. 12 is a schematic diagram illustrating a configuration of a semiconductor laser device according to a sixth embodiment of the present invention.

### DESCRIPTION OF EMBODIMENTS

A semiconductor laser device according to certain embodiments of the present invention will be described in detail below with reference to the drawings. Note that the present invention is not limited to the embodiments.

### First Embodiment

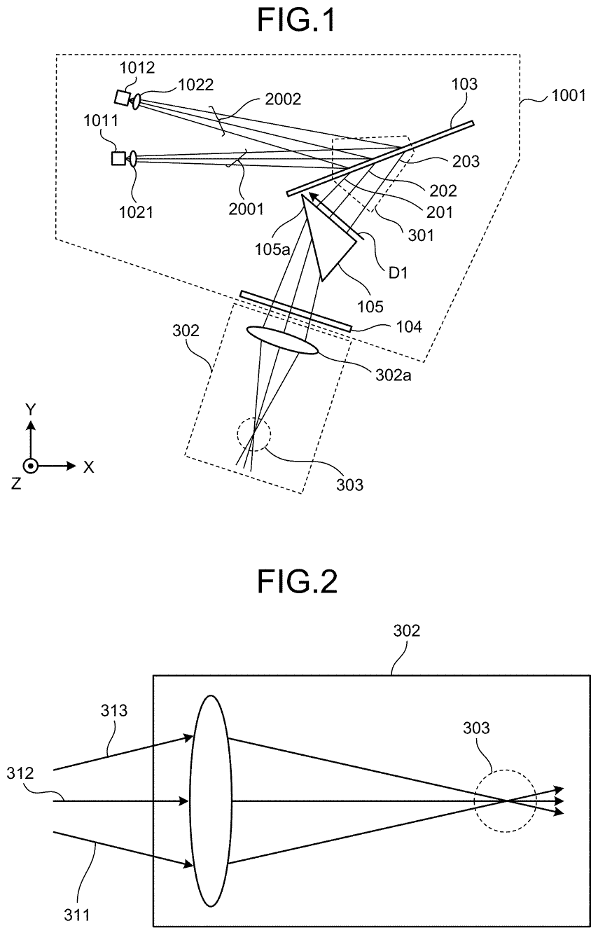

FIG. 1 is a schematic diagram illustrating a configuration of a semiconductor laser device 1001 according to a first embodiment of the present invention. In FIG. 1, an X axis, a Y axis, and a Z axis of a three-axis Cartesian coordinate system are illustrated.

The semiconductor laser device 1001 includes a plurality of semiconductor laser elements 1011 and 1012 that emit laser beams having different wavelengths from each other. A laser beam 2001 emitted by the semiconductor laser element 1011 is incident on a transmissive wavelength dispersion element 103 via a divergence angle correction element 1021 that corrects beam divergence angles. A laser beam 2002 emitted by the semiconductor laser element 1012 is incident on the transmissive wavelength dispersion element 103 via a divergence angle correction element 1022 that corrects beam divergence angles.

The semiconductor laser elements 1011 and 1012 constitute one end of an external resonator, and a partial reflection element 104 constitutes the other end of the external resonator. In other words, the partial reflection element 104 and the semiconductor laser elements 1011 and 1012 constitute respective ends of the external resonator. The transmissive wavelength dispersion element 103 is located on an optical path of laser beams between the semiconductor laser elements 1011 and 1012 and the partial reflection element 104, and is located in a deflection part 301 including the positions at which the laser beams 2001 and 2002 are superimposed. The transmissive wavelength dispersion element 103 changes the traveling directions of the laser beams 2001 and 2002 by the wavelength dispersion property within an XY plane, which is a first plane including the optical axes of the laser beams 2001 and 2002. As a result, the laser beams 2001 and 2002 are combined into one beam having one common optical axis. The transmissive wavelength dispersion element 103 is a transmission grating, a prism, or the like, for example.

The partial reflection element 104 reflects part of the beam obtained by combining the laser beams 2001 and 2002 back to the transmissive wavelength dispersion element 103, and outputs the remaining part to the outside of the external resonator. While the partial reflection element 104 reflects part of the entire beam cross sections of the laser beams 2001 and 2002 in FIG. 1, the partial reflection element 104 may be a scraper mirror that transmits part of a beam cross section of incident light to the outside and reflects the remaining part so as to constitute an unstable resonator.

An asymmetric refraction optical element 105 is located on an optical path between the transmissive wavelength dispersion element 103 and the partial reflection element 104. In the asymmetric refraction optical element 105, the angle of an emission surface 105a with respect to incident light varies depending on the position in a first direction D1, which is a direction included in the XY plane and perpendicular to the optical axis of the laser beam. Thus, the change in angle at the emission surface 105a varies depending on the position in the first direction D1. The asymmetric refraction optical element 105 therefore causes the optical path length from the emission surface 105a to the partial reflection element 104 to differ depending on the position in the first direction D1.

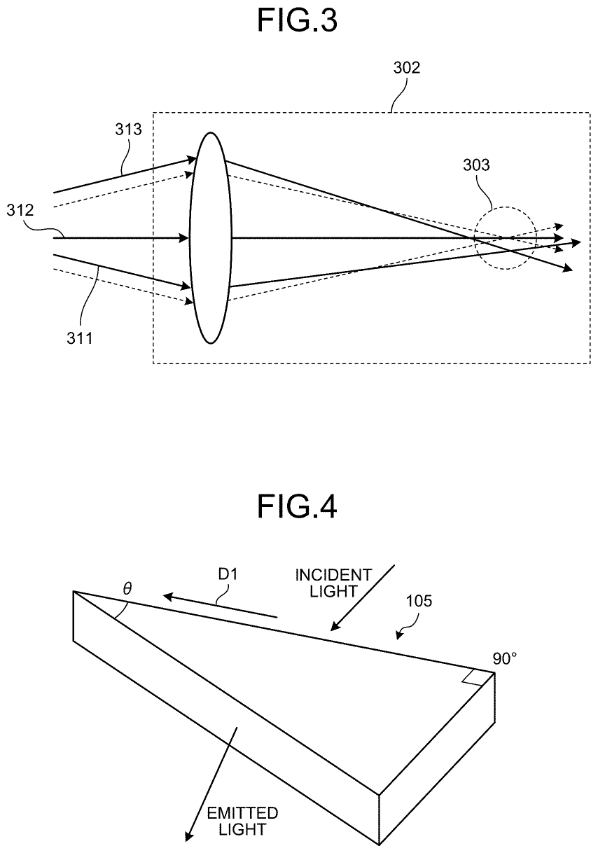

An external optical system 302 includes a condenser lens 302a, and focuses the laser beam emitted by the semiconductor laser device 1001 to a focus point 303. FIG. 2 is a schematic diagram illustrating an example of a light focusing state of an aberration-free optical system. FIG. 3 is a schematic diagram illustrating an example of a light focusing state of an optical system with an aberration. Among a large number of rays in a beam, a main ray 312 that passes along the optical axis of the beam, a lower ray 311 that passes on the lower side of the beam axis through the lens, and an upper ray 313 that passes on the upper side of the beam axis through the lens are illustrated. In the aberration-free case, as illustrated in FIG. 2, the main ray 312, the upper ray 313, and the lower ray 311 meet at one point, that is, the focus point 303 formed by the external optical system 302.

In contrast, in the case with an aberration, as illustrated in FIG. 3, the main ray 312, the upper ray 313, and the lower ray 311 do not meet at one point at the focus point 303 formed by the external optical system 302. Thus, in the case with an aberration, the focusing performance is lowered, and the energy density of laser beams at the focus point 303 may be lowered or the beam profile may become asymmetric.

In the semiconductor laser device 1001 illustrated in FIG. 1, the optical path lengths of the laser beams 2001 and 2002 differ from each other in the deflection part 301; therefore, the focusing performance lowers as illustrated in FIG. 3 when the asymmetric refraction optical element 105 is not included. In the semiconductor laser device 1001, the optical path difference caused in the deflection part 301 is reduced by the asymmetric refraction optical element 105. The beam focusing performance is thus improved.

The configurations of the respective components of the semiconductor laser device 1001 will be described in more detail. While the semiconductor laser device 1001 includes two semiconductor laser elements 1011 and 1012 in FIG. 1, three or more semiconductor laser elements may be included. In addition, the semiconductor laser elements 1011 and 1012 herein are edge-emitting single emitter semiconductor laser elements including a Fabry-Perot resonator. An edge-emitting semiconductor laser including a Fabry-Perot resonator has a fast axis along which the beam divergence angle is large, and a slow axis which is perpendicular to the fast axis and along which the beam divergence angle is small. In FIG. 1, the fast axis is within the XY plane, and the slow axis corresponds to the Z-axis direction. The semiconductor laser elements 1011 and 1012 have wavelengths from 400 nm to 1100 nm with which fiber coupling is easily made, for example. In particular, in the wavelength in a range of about 900 nm to 1000 nm, elements having a higher power and a longer lifetime than the other wavelength ranges are commercially available; therefore, such a wavelength is preferable for high-power applications such as laser beam machining. The above is, however, an example, and the semiconductor laser elements 1011 and 1012 of the present embodiment may be of a surface-emitting type, for example, and the resonator may have various configurations such as a flared resonator or a folded resonator.

The laser beams 2001 and 2002 emitted from the semiconductor laser elements 1011 and 1012 are incident on the divergence angle correction elements 1021 and 1022, respectively, in the fast axis direction. The laser beams 2001 and 2002 emitted from the divergence angle correction elements 1021 and 1022 are incident on the transmissive wavelength dispersion element 103.

The beam cross sections of the laser beams 2001 and 2002 are superimposed at the position of the transmissive wavelength dispersion element 103. In FIG. 1, the beam cross sections are superimposed by adjusting the arrangement of the semiconductor laser elements 1011 and 1012 and the transmissive wavelength dispersion element 103. The beam cross sections may be superimposed by adjusting the arrangement of the semiconductor laser elements 1011 and 1012 in this manner, or the beam cross sections may be superimposed by adjusting the optical paths of the laser beams 2001 and 2002 by optical elements that are additionally provided on the optical paths.

The transmissive wavelength dispersion element 103 has a wavelength dispersion property in an XY in-plane direction of the laser beams. The transmissive wavelength dispersion element 103 deflects the laser beams at angles depending on the wavelengths in the XY plane to combine the laser beams into a beam having one optical axis. When the laser beams pass through the deflection part 301, a difference is caused between the optical path lengths thereof depending on the positions in the beam cross sections in the XY plane. Such a difference between the optical path lengths causes the deterioration in the focusing performance of beams output from the external resonator.

The internal passage distance in the asymmetric refraction optical element 105, which is a distance by which the laser beams pass through the asymmetric refraction optical element 105, decreases with a change in the position in the first direction D1 that is the beam cross section direction in the XY plane. The asymmetric refraction optical element 105 illustrated in FIG. 1 is made of a material having a higher refractive index than that of a free space. Herein, an area around the semiconductor laser elements 1011 and 1012 and optical elements will be referred to as the free space. When the refractive index of the asymmetric refraction optical element 105 is higher than that of the free space, the first direction D1 is a direction from an outer ray 203, which passes a longer distance from the transmissive wavelength dispersion element 103 to the asymmetric refraction optical element 105, toward an inner ray 201, which passes a shorter distance, as illustrated in FIG. 1. In a case where the asymmetric refraction optical element 105 is made of a material having a refractive index lower than that of the free space, however, the first direction D1 is a direction from the inner ray 201 toward the outer ray 203.

In FIG. 1, a main ray 202, the inner ray 201, and the outer ray 203 are illustrated. The main ray 202 corresponds to the optical axis of the laser beam. The inner ray 201 and the outer ray 203 correspond to geometric optical paths. The inner ray 201 is incident on the transmissive wavelength dispersion element 103 on the inner side of the deflection angle with respect to the main ray 202, and the outer ray 203 is incident on the transmissive wavelength dispersion element 103 on the outer side of the deflection angle with respect to the main ray 202.

When the laser beams change the traveling directions at the transmissive wavelength dispersion element 103, the asymmetric refraction optical element 105 functions such that the inner ray 201 with an optical path length shorter than that of the main ray 202 will have a longer optical length to the partial reflection element 104 after passing through the asymmetric refraction optical element 105 than that of the main ray 202. The asymmetric refraction optical element 105 functions such that the outer ray 203 with an optical path length longer than that of the main ray 202 will have a shorter optical path length to the partial reflection element 104 after passing through the asymmetric refraction optical element 105 than that of the main ray 202. As a result, the variation of the rays at the focus point 303 is reduced. Thus, effects of reducing the aberration and reducing deterioration in the focusing performance of output beams can be produced.

FIG. 4 is a schematic view illustrating an example of a configuration of the asymmetric refraction optical element 105 illustrated in FIG. 1. The asymmetric refraction optical element 105 illustrated in FIG. 4 is a prism having a shape of a triangular prism with a right-angled-triangular base. An optical material such as synthetic silica is suitable for the material of the prism, and a low reflection coating is applied to the light incidence surface and the light emission surface thereof where necessary. A vertex angle θ of the triangle may be any angle that can reduce the optical path difference between the outer ray 203 and the inner ray 201. More preferably, the optical path difference between the outer ray 203 and inner ray 201 caused in the deflection part 301 may be compensated for by calculating an aberration caused in the deflection part 301, designing the vertex angle θ in view of the refractive index of the material of the asymmetric refraction optical element 105, and calculating the intra-element passage distance through the asymmetric refraction optical element 105 depending on the position in the cross section, to obtain an output beam with high focusing performance.

The asymmetric refraction optical element 105 is positioned such that a side face corresponding to the hypotenuse of the right-angled triangle is the emission surface. As a result, the intra-element passage distance decreases linearly with respect to the distance in the first direction D1. Note that, in the Z-axis direction, which is a direction perpendicular to the first direction D1, the intra-element passage distance is constant.

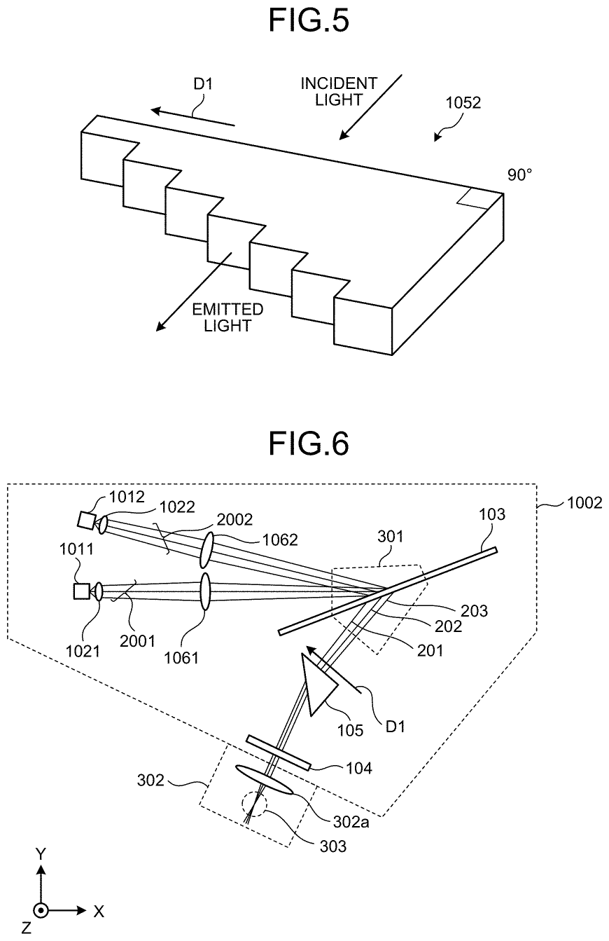

FIG. 5 is a schematic view illustrating a configuration of an asymmetric refraction optical element 1052, which is a modification of FIG. 4. The asymmetric refraction optical element 1052 is an element of a high-refractive-index material having a stepped shape. The shape of the asymmetric refraction optical element 105 is not limited to the examples illustrated in FIGS. 4 and 5, and may be any shape with which the intra-element passage distance varies depending on the position of the beam cross section in the first direction D1. In addition, while the asymmetric refraction optical element 105 is a single optical element in FIGS. 1, 4, and 5, the asymmetric refraction optical element 105 may be constituted by a plurality of optical elements.

In recent years, machining laser power has been becoming higher, and beams from more semiconductor laser elements need to be combined within a limited wavelength range. In such a laser device, the beam diameter on a wavelength dispersion element needs to be large so that a beam incidence angle with respect to a wavelength dispersion element is increased and the wavelength resolution of the wavelength dispersion optical element is increased. The beam incidence angle is an angle between a ray incident on an element and the normal to an incidence surface. In such a laser device, because the focusing performance in the wavelength dispersion direction in the wavelength dispersion element, that is, in the first direction D1 illustrated in FIG. 1, is significantly lowered, application of the technology of the embodiment described above is expected to produce significant advantageous effects.

For example, in a case where the wavelengths of the beams output from the semiconductor laser elements 1011 and 1012 are in a range from 900 nm to 1100 nm and a transmission grating having 1500 or more grooves/mm is used for the transmissive wavelength dispersion element 103, the incidence angle of laser beams with respect to the transmissive wavelength dispersion element 103 is 40 degrees or larger in an optical arrangement close to a Littrow arrangement, for example, with which the largest diffraction effect is obtained. Under such a condition, because the aberration caused in the deflection part 301 by the transmissive wavelength dispersion element 103 is large, application of the technology of the present embodiment is expected to produce significant advantageous effects. Furthermore, in a case where the beam diameter in the first direction D1 on the transmissive wavelength dispersion element 103 is 30 mm or larger in the knife-edge width, the aberration caused by the transmissive wavelength dispersion element 103 is particularly large. The aberration reducing effect produced by applying the technology of the present embodiment is therefore increased.

Note that the knife-edge width dx is expressed by the following formula (1) where a position at which an accumulated energy obtained by accumulating energy in the first direction D1 of the beam cross section reaches 16% is represented by x1, and a position at which the accumulated energy reaches 84% is represented by x2.

dx=2×(x2−x1) (1)

The fact that the aberration in the beam cross section caused in the deflection part 301 has a great influence on the focusing performance in the wavelength beam combining external resonator described in the present embodiment has not been known. This is considered to be because wavelength beam combining external resonators have been developed in complicated systems in which many beams are combined. In complicated systems in which many beams are combined, there have been many factors that lower the focusing performance, such as deviations in characteristics between beams subjected to wavelength beam combining, the influence of the smile of a semiconductor laser array, and the influence of cross-coupling oscillation. It has therefore been difficult to analyze these factors separately, no attention has been paid to the influence of an aberration occurring in the deflection part 301, and no measures has been taken. The present inventors have focused on the aberration occurring in the deflection part 301 and proposed solutions for the first time.

Note that, when the asymmetric refraction optical element 105 is located in the wavelength beam combining external resonator, the focusing performance of wavelength-combined beams may be lowered by the wavelength dispersion property of the asymmetric refraction optical element 105. In the configuration of the present embodiment, however, the deterioration in the focusing performance due to the wavelength dispersion property of the asymmetric refraction optical element 105 is sufficiently smaller than the focusing performance improvement effect produced by the asymmetric refraction optical element 105. Specifically, a configuration in which an optical element made of glass such as silica glass or SF10 is used to eliminate the aberration by a difference in distance by which laser beams pass through the part made of glass can make the focusing performance improvement effect greater than the deterioration in the focusing performance at least by an order of magnitude.

As described above, in the semiconductor laser device 1001 according to the first embodiment of the present invention, the intra-element passage distance, which is a distance by which the laser beams pass through the asymmetric refraction optical element 105, decreases with a change in the position in the first direction D1 in the XY plane, which is the first plane. Although the optical path length in the deflection part 301 becomes shorter from the outer side toward the inner side of the turn of the rays of the laser beams 2001 and 2002, use of the asymmetric refraction optical element 105 having the intra-element passage distance as described above makes the optical path length from the emission surface 105a of the asymmetric refraction optical element 105 to the partial reflection element 104 longer from the outer side toward the inner side of the turn of the rays of the laser beams 2001 and 2002. The asymmetric refraction optical element 105 can therefore reduce the aberration in the semiconductor laser device 1001. The semiconductor laser device 1001 is therefore capable of generating high-power laser beams with high focusing performance.

### Second Embodiment

FIG. 6 is a schematic diagram illustrating a configuration of a semiconductor laser device 1002 according to a second embodiment of the present invention. The semiconductor laser device 1002 includes, in addition to the configuration of the semiconductor laser device 1001 illustrated in FIG. 1, a condenser lens 1061 located on the optical path between the divergence angle correction element 1021 and the transmissive wavelength dispersion element 103, and a condenser lens 1062 located on the optical path between the divergence angle correction element 1022 and the transmissive wavelength dispersion element 103. Hereinafter, components similar to those of the semiconductor laser device 1001 will be represented by the same reference numerals, detailed description thereof will not be repeated, and differences from the semiconductor laser device 1001 will be mainly described.

In the semiconductor laser device 1002, in a manner similar to the semiconductor laser device 1001, when the traveling directions of the laser beams 2001 and 2002 are changed by the transmissive wavelength dispersion element 103, the optical path length of the inner ray 201 is longer than that of the main ray 202 and the optical path length of the outer ray 203 is shorter than that of the main ray 202. The asymmetric refraction optical element 105 functions such that the inner ray 201 with an optical path length made to be shorter than that of the main ray 202 by light refraction will have a longer optical path length to the partial reflection element 104 after passing through the asymmetric refraction optical element 105 than that of the main ray 202. In addition, the asymmetric refraction optical element 105 functions such that the outer ray 203 with an optical path length made to be longer than that of the main ray 202 by light refraction will have a shorter optical path length to the partial reflection element 104 after passing through the asymmetric refraction optical element 105 than that of the main ray. As a result, the aberration caused by the optical path length difference between the laser beams 2001 and 2002 caused by the transmissive wavelength dispersion element 103 in the direction including the first direction D1 can be reduced. The deterioration in the focusing performance can therefore be reduced.

In addition, in the semiconductor laser device 1002, the functions of the condenser lenses 1061 and 1062 make the beam diameter at the transmissive wavelength dispersion element 103 smaller than that in the semiconductor laser device 1001. Thus, the amount of the aberration occurring in the deflection part 301 can be reduced. In addition, the beam diameter after the combination by the transmissive wavelength dispersion element 103 is also smaller than that in the semiconductor laser device 1001. Thus, the distance to the focus point 303 in the external optical system 302 can be made shorter, and the size of the entire optical system can be made smaller.

As described above, according to the second embodiment of the present invention, at least part of an aberration occurring in the deflection part 301 and being dependent on the position in the first direction D1 in the beam cross section can be compensated for in a manner similar to the first embodiment. Thus, high-power laser beams with high focusing performance can be generated by using a plurality of laser beams 2001 and 2002 emitted by a plurality of semiconductor laser elements 1011 and 1012 and using a dispersive element.

In addition, an aberration caused in the deflection part 301 can be reduced upon occurrence thereof by reducing the beam diameters of the laser beams 2001 and 2002 incident on the transmissive wavelength dispersion element 103.

### Third Embodiment

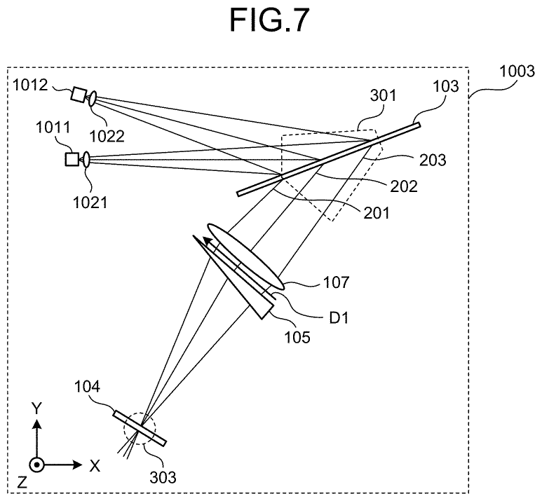

FIG. 7 is a schematic diagram illustrating a configuration of a semiconductor laser device 1003 according to a third embodiment of the present invention. The semiconductor laser device 1003 includes, in addition to the configuration of the semiconductor laser device 1001, a condenser lens 107 located on the optical path between the transmissive wavelength dispersion element 103 and the asymmetric refraction optical element 105. Hereinafter, components similar to those of the semiconductor laser device 1001 will be represented by the same reference numerals, detailed description thereof will not be repeated, and differences from the semiconductor laser device 1001 will be mainly described.

The condenser lens 107 changes the angle of incidence of the laser beams on the asymmetric refraction optical element 105 and the ray heights thereof. As a result, the optical path length difference between the optical paths, which is a cause of an aberration, can be converted into a converging angle difference and a ray height difference. The asymmetric refraction optical element 105 can therefore be reduced in size. Note that the ray height refers to the height of a ray measured from the optical axis in the direction perpendicular to the optical axis.

In a case where the semiconductor laser elements 1011 and 1012 are assumed to be point light sources, when the ray height in a direction perpendicular to the main ray 202 is represented by h and the converging angle is represented by α, rays in a single beam are converged in a state in which the proportional relation between the ray height h and the tangent tan α of the converging angle α is maintained in an aberration-free optical system. In this case, all the rays converge to a point. In contrast, in an optical diameter with an aberration, the relation between the ray height h and the converging angle α is not maintained, and the rays do not converge to a point.

In a case where no asymmetric refraction optical element 105 is provided before the partial reflection element 104, the inner ray 201, the main ray 202, and the outer ray 203 do not converge at a point, that is, the focus point 303 owing to the influence of the optical path length difference caused by the transmissive wavelength dispersion element 103. In contrast, in the present embodiment, the asymmetric refraction optical element 105 is provided, which changes the ray height h and the converging angle α of each ray by the refracting function to make the ray height h and the tangent tan α of the converging angle α closer to the proportional state, and the aberration is thus reduced. Although the semiconductor laser elements 1011 and 1012 are assumed to be point light sources herein for simplicity, an aberration reducing effect similar to that described above can also be produced on laser beams emitted from actual semiconductor laser elements 1011 and 1012.

As described above, according to the third embodiment of the present invention, at least part of an aberration occurring in the deflection part 301 and being dependent on the position in the first direction D1 in the beam cross section can be compensated for in a manner similar to the first embodiment. Thus, high-power laser beams with high focusing performance can be generated by using a plurality of laser beams 2001 and 2002 emitted by a plurality of semiconductor laser elements 1011 and 1012 and using a dispersive element.

In addition, in the present embodiment, an optical path length difference between the optical paths, which is a cause of an aberration, is converted into a converging angle difference and a ray height difference by the condenser lens 107, which can produce effects of being capable of further reducing the asymmetric refraction optical element 105 in size and capable of miniaturizing the semiconductor laser device 1003 as compared with the first and second embodiments.

### Fourth Embodiment

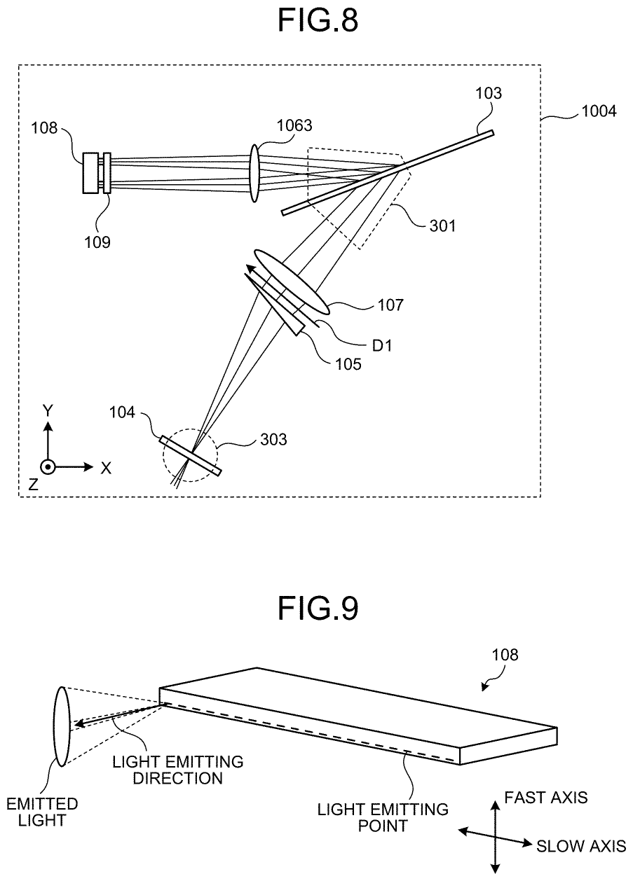

FIG. 8 is a schematic diagram illustrating a configuration of a semiconductor laser device 1004 according to a fourth embodiment of the present invention. The semiconductor laser device 1004 includes the functions of the condenser lenses 1061 and 1062 described in the second embodiment, and the condenser lens 107 described in the third embodiment. Thus, the two effects of reducing the aberration caused in the deflection part 301 and reducing the size of the asymmetric refraction optical element 105 can be produced at the same time.

In addition, in the semiconductor laser device 1004, a semiconductor laser array element 108 integrating a plurality of semiconductor laser elements is used as a light source. Thus, while the divergence angle correction elements 1021 and 1022 and the condenser lenses 1061 and 1062 are provided in association with the semiconductor laser elements 1011 and 1012, respectively, in the second embodiment, a divergence angle correction element 109 and a condenser lens 1063 are provided over a plurality of optical paths of a plurality of laser beams emitted by the semiconductor laser array element 108 in the fourth embodiment.

FIG. 9 is a schematic view illustrating a configuration of the semiconductor laser array element 108 illustrated in FIG. 8. The fast-axis direction of the semiconductor laser array element 108 corresponds to the Z-axis direction, and the slow-axis direction thereof corresponds to the Y-axis direction. The semiconductor laser array element 108 includes a plurality of light emitting points. In FIG. 9, emitted light 401 from each of the light emitting points and a light emitting direction 402 are illustrated. The semiconductor laser array element 108 illustrated in FIG. 9 emits a plurality of beams having optical axes parallel to each other. The condenser lens 1063 has, in addition to a function of changing the spread angles of the beams, a function of changing the traveling directions of the beams to superimpose the beams at a position.

In addition, in an edge-emitting semiconductor laser bar, elements are typically arranged in the slow-axis direction, and the divergence angle correction element 109 that is a cylindrical lens is used as a lens for correcting the beam divergence angle in the fast-axis direction. In the present embodiment, the beams are combined by the transmissive wavelength dispersion element 103 in the slow-axis direction, and an aberration in the deflection part 301 also occurs in the slow-axis direction. Thus, the condenser lens 1063, the condenser lens 107, and the asymmetric refraction optical element 105 relating to reduction of the aberration are arranged to have power in the slow-axis direction.

In addition, in the semiconductor laser array element 108, semiconductor laser elements are closely arranged at a narrow pitch. Thus, more beams are incident at a narrow angle and are subjected to wavelength beam combining than those in a single-chip laser diode. Thus, the transmissive wavelength dispersion element 103 needs to have a higher angular resolution. In order to increase the angular resolution of the transmissive wavelength dispersion element 103, the beam diameter on the transmissive wavelength dispersion element 103 needs to be increased. The aberration in the beam cross section occurring in the deflection part 301 thus becomes larger, and the advantageous effects of the present invention are increased.

As described above, according to the fourth embodiment of the present invention, at least part of an aberration occurring in the deflection part 301 and being dependent on the position in the first direction D1 in the beam cross section can be compensated for in a manner similar to the first embodiment. Thus, high-power laser beams with high focusing performance can be generated by using a plurality of laser beams emitted by the semiconductor laser array element 108 and using a dispersive element.

Furthermore, because the condenser lens 1063 and the condenser lens 107 are included in the present embodiment, the effect of reducing an aberration upon occurrence thereof in the deflection part 301 as described in the second embodiment and the effect of enabling reduction of the asymmetric refraction optical element 105 in size as described in the third embodiment can be produced at the same time.

In addition, because the semiconductor laser array element 108 including a plurality of semiconductor laser elements is used, high-power laser beams with high focusing performance can be generated by the semiconductor laser device having a simple structure with a small number of components.

### Fifth Embodiment

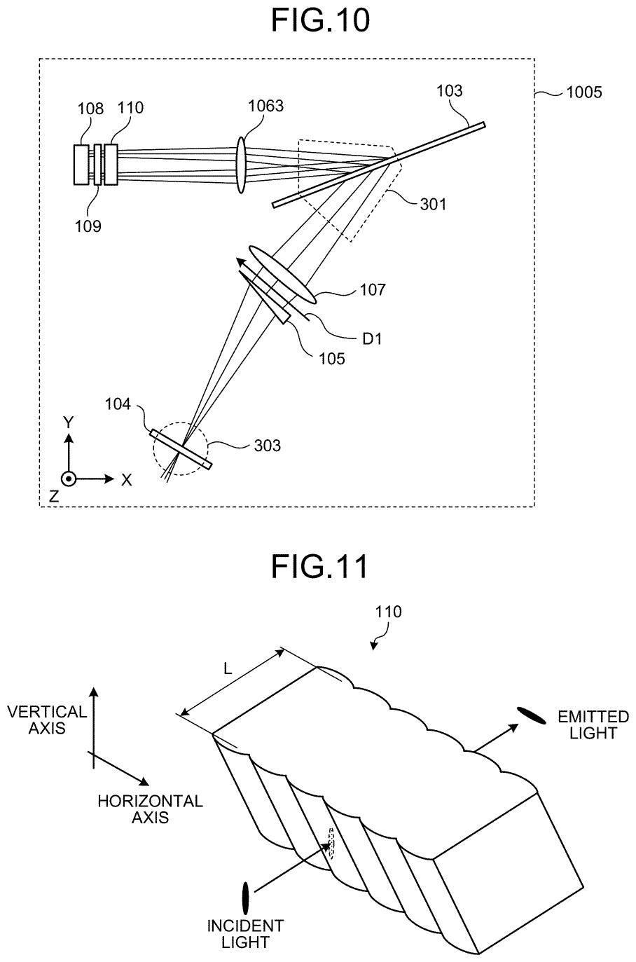

FIG. 10 is a schematic diagram illustrating a configuration of a semiconductor laser device 1005 according to a fifth embodiment of the present invention. The semiconductor laser device 1005 includes, in addition to the configuration of the semiconductor laser device 1004 according to the fourth embodiment, a rotating optical element 110 that is located on the optical path between the divergence angle correction element 109 in the fast-axis direction and the transmissive wavelength dispersion element 103 and that superimposes the beams on the transmissive wavelength dispersion element 103 while performing image rotation around the optical axis.

FIG. 11 is a perspective view illustrating an example of a configuration of the rotating optical element 110 illustrated in FIG. 10. The rotating optical element 110 is a 90-degree image rotation optical system array that rotates a plurality of incident laser beams individually by 90 degrees around the optical axis as a rotation axis and emits the rotated laser beams. The rotating optical element 110 is disposed in a YZ plane at an inclined angle of 45 degrees with respect to the Y axis. The rotating optical element 110 includes a plurality of pairs of cylindrical convex lenses arranged at an inclined angle of 45 degrees with respect to the horizontal axis. The cylindrical convex lenses are arranged at the same pitch as the arrangement of the light emitting points included in the semiconductor laser array element 108. When the focal distance of the cylindrical convex lenses is represented by f, the distance L between a pair of cylindrical convex lenses is 2f. When a beam is incident on the rotating optical element 110 as described above, a beam in a state in which the vertical-axis direction and the horizontal-axis direction are replaced each other is emitted. Such a rotating optical element 110 is commercialized and readily available. A wavelength beam combining external resonator including the rotating optical element 110 is also taught by International publication No. WO 2014/087726, and similar technology can be applied.

The edge-emitting semiconductor laser array element 108 as illustrated in FIG. 9 is often used in cases where a plurality of semiconductor laser elements are arranged side by side. In such a semiconductor laser array element 108, while the beam divergence angle on the slow axis, which is the direction of arrangement of the light emitting points, is typically about 5 to 10 degrees in full angle, the beam divergence angle in the fast-axis direction perpendicular to the direction of arrangement is about 30 to 60 degrees, which is larger. In addition, the focusing performance is typically lower in the slow-axis direction than in the fast-axis direction. In the semiconductor laser array element 108, deformation called a smile of an element caused in a manufacturing process may occur, which may cause variation in installation heights of light sources in the fast-axis direction. In the present embodiment, the rotating optical element 110 is used to rotate the laser beams by 90 degrees around the optical axis, whereby the influence of the smile in the fast-axis direction can be converted to the slow-axis direction in which the focusing performance is relatively low.

As a result, the semiconductor laser device 1005 can reduce the rate of deterioration in the focusing performance caused by the smile, which produces an effect of being capable of stably superimposing outputs from a plurality of semiconductor laser elements to achieve high power.

As described above, according to the semiconductor laser device 1005 in the fifth embodiment of the present invention, at least part of an aberration occurring in the deflection part 301 and being dependent on the position in the first direction D1 in the beam cross section can be compensated for in a manner similar to the first embodiment. Thus, high-power laser beams with high focusing performance can be generated by using a plurality of laser beams emitted by the semiconductor laser array element 108 and using a dispersive element.

Furthermore, in the present embodiment, because the rotating optical element 110 is used, the influence of the smile in the fast-axis direction can be converted to the slow-axis direction in which the focusing performance is relatively low. The deterioration in the focusing performance caused by the smile can therefore be reduced, and an effect of stably superimposing outputs from a plurality of semiconductor laser elements to achieve high power can be produced.

### Sixth Embodiment

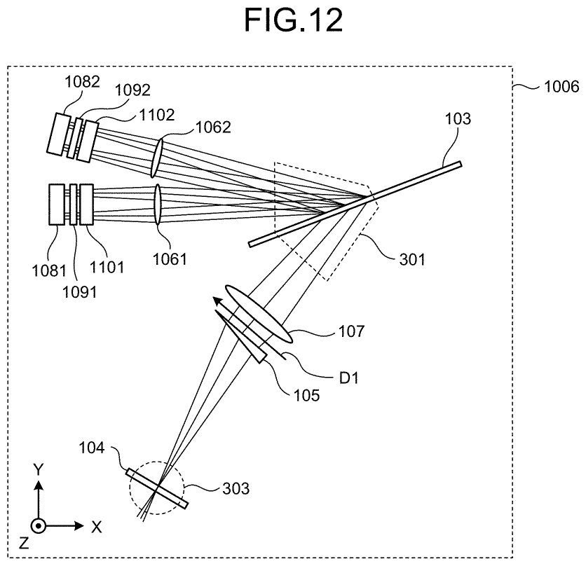

FIG. 12 is a schematic diagram illustrating a configuration of a semiconductor laser device 1006 according to a sixth embodiment of the present invention. The semiconductor laser device 1006 includes a plurality of semiconductor laser array elements 1081 and 1082. The semiconductor laser array elements 1081 and 1082 can have a configuration similar to that of the semiconductor laser array element 108 illustrated in FIG. 9. While two semiconductor laser array elements 1081 and 1082 are presented herein, three or more semiconductor laser array elements 108 may be used.

The semiconductor laser device 1006 includes two divergence angle correction elements 1091 and 1092 and two rotating optical elements 1101 and 1102 provided in association with the two semiconductor laser array elements 1081 and 1082, respectively.

In addition, in order that the outputs from a plurality of semiconductor laser array elements 1081 and 1082 are superimposed, beams are incident on the transmissive wavelength dispersion element 103 from a wider angular range than in a case where one semiconductor laser array element 108 is used. Thus, a beam incident on the transmissive wavelength dispersion element 103 at a large incidence angle is deflected at a large deflection angle in the deflection part 301, which also increases an aberration caused by the optical path length difference in the deflection part 301. Thus, in the semiconductor laser device 1006 including the wavelength beam combining external resonator using a plurality of semiconductor laser array elements 1081 and 1082, the advantageous effects produced by applying the technology of the present embodiment is increased.

As described above, according to the semiconductor laser device 1006 in the sixth embodiment of the present invention, at least part of an aberration occurring in the deflection part 301 and being dependent on the position in the first direction D1 in the beam cross section can be compensated for in a manner similar to the first embodiment. Thus, high-power laser beams with high focusing performance can be generated by using a plurality of laser beams emitted by the semiconductor laser array elements 1081 and 1082 and using a dispersive element.

Furthermore, in the present embodiment, because a plurality of semiconductor laser array elements 1081 and 1082 are used, more laser beams output from more semiconductor laser elements are combined, which can produce an effect of being capable of achieving higher power than the case where one semiconductor laser array element 108 is used.

While the configurations of the semiconductor laser devices 1001 to 1006 have been described in the embodiments, the technologies described in the embodiments can also be implemented as a laser machining apparatus including any of the semiconductor laser devices 1001 to 1006.

The configurations presented in the embodiments above are examples of the present invention, and can be combined with other known technologies or can be partly omitted or modified without departing from the scope of the present invention.

For example, while examples in which one semiconductor laser array element 108 is used as a light source are presented in the fourth and fifth embodiments and an example in which two semiconductor laser array elements 1081 and 1082 are used as light sources is presented in the sixth embodiment, the present invention is not limited to the examples. It is sufficient if at least one of the semiconductor laser elements is constituted by a semiconductor laser array element 108. In other words, the semiconductor laser devices 1004 to 1006 are not limited to the examples in which all of the semiconductor laser elements are the semiconductor laser array elements 108, but may include both of the semiconductor laser array elements 108 and semiconductor laser elements that are single-chip laser diodes. In addition, the semiconductor laser devices 1004 to 1006 may include three or more semiconductor laser array elements 108.

### REFERENCE SIGNS LIST

103 transmissive wavelength dispersion element; 104 partial reflection element; 105 asymmetric refraction optical element; 105a emission surface; 107, 302a, 1061, 1062, 1063 condenser lens; 108, 1081, 1082 semiconductor laser array element; 109, 1021, 1022, 1091, 1092 divergence angle correction element; 110, 1101, 1102 rotating optical element; 201 inner ray; 202 main ray; 203 outer ray; 301 deflection part; 302 external optical system; 303 focus point; 1001 to 1006 semiconductor laser device; 1011, 1012 semiconductor laser element; 2001, 2002 laser beam; D1 first direction; θ vertex angle; a converging angle; h ray height.

1. A semiconductor laser device comprising:
a plurality of semiconductor laser elements to emit laser beams having different wavelengths from each other;
a partial reflection element, the semiconductor laser elements and the partial reflection element constituting respective ends of an external resonator;
a transmissive wavelength dispersion element located on optical paths of the laser beams between the semiconductor laser elements and the partial reflection element and at a position at which the laser beams are superimposed, the transmissive wavelength dispersion element having a wavelength dispersion property and changing traveling directions of the laser beams in a first plane including optical axes of the laser beams to combine the laser beams to have one optical axis;
an asymmetric refraction optical element located on an optical path between the transmissive wavelength dispersion element and the partial reflection element, an intra-element passage distance in the asymmetric refraction optical element decreasing with a change in a position in a first direction, the intra-element passage distance being a distance by which a laser beam passes through the asymmetric refraction optical element, the first direction being a direction included in the first plane and perpendicular to the optical axis of the laser beams; and
a condenser lens located on an optical path between the transmissive wavelength dispersion element and the asymmetric refraction optical element.

2. The semiconductor laser device according to claim 1, wherein the transmissive wavelength dispersion element is a transmission grating.

3. The semiconductor laser device according to claim 1, wherein
the asymmetric refraction optical element is made of a material having a higher refractive index than a free space, and
the first direction is a direction from a side on which a distance from the transmissive wavelength dispersion element to the asymmetric refraction optical element is longer to a side on which the distance is shorter.

4. The semiconductor laser device according to claim 3, wherein the intra-element passage distance in the asymmetric refraction optical element decreases linearly with respect to a distance in the first direction.

5. The semiconductor laser device according to claim 3, wherein the intra-element passage distance in the asymmetric refraction optical element decreases in a stepwise manner per predetermined distance in the first direction.

6. The semiconductor laser device according to claim 1, further comprising a divergence angle correction element located between the semiconductor laser element and the transmissive wavelength dispersion element, the divergence angle correction element correcting divergence angles of the laser beams.

7. The semiconductor laser device according to claim 6, further comprising a condenser lens located on an optical path between the divergence angle correction element and the transmissive wavelength dispersion element.

8. (canceled)

9. The semiconductor laser device according to claim 1, further comprising a rotating optical element located on optical paths between the semiconductor laser elements and the transmissive wavelength dispersion element, the rotating optical element rotating the incident laser beams individually by 90 degrees around an optical axis as a rotation axis and emitting the rotated laser beams.

10. The semiconductor laser device according to claim 1, wherein at least one of the semiconductor laser elements is constituted by a semiconductor laser array element.

11. A semiconductor laser device comprising:
a plurality of semiconductor laser elements to emit laser beams having different wavelengths from each other;
a partial reflection element, the semiconductor laser elements and the partial reflection element constituting respective ends of an external resonator;
a transmissive wavelength dispersion element located on optical paths of the laser beams between the semiconductor laser elements and the partial reflection element and at a position at which the laser beams are superimposed, the transmissive wavelength dispersion element having a wavelength dispersion property and changing traveling directions of the laser beams in a first plane including optical axes of the laser beams to combine the laser beams to have one optical axis; and
an asymmetric refraction optical element located on an optical path between the transmissive wavelength dispersion element and the partial reflection element, an intra-element passage distance in the asymmetric refraction optical element decreasing with a change in a position in a first direction, the intra-element passage distance being a distance by which a laser beam passes through the asymmetric refraction optical element, the first direction being a direction included in the first plane and perpendicular to the optical axis of the laser beams, wherein
the first direction is a direction from a side on which a distance from the transmissive wavelength dispersion element to the asymmetric refraction optical element is longer to a side on which the distance is shorter, and
the asymmetric refraction optical element is made of a material having a higher refractive index than a free space, and the intra-element passage distance decreases in a stepwise manner per predetermined distance in the first direction.
